(19) United States
(12) Patent Application Publication
(10) Pub. No.: US 2016/0186055 A1
(43) Pub. Date: Jun. 30, 2016

(54) GREEN LIGHT EMITTING PHOSPHOR, METHOD FOR PRODUCING THE SAME AND LIGHT EMITTING DEVICE PACKAGE INCLUDING THE SAME

(71) Applicant: LG ELECTRONICS INC., Yeongdeungpo-gu, Seoul (KR)

(72) Inventors: Younggil YOO, Seoul (KR); Gunyoung HONG, Seoul (KR); Soongil KIM, Seoul (KR); Kyungpil KIM, Seoul (KR)

(21) Appl. No.: 14/781,662

(22) PCT Filed: Aug. 28, 2014
(86) PCT No.: PCT/KR2014/008013

§ 371 Date: Oct. 1, 2015

(30) Foreign Application Priority Data
Oct. 21, 2013 (KR) 10-2013-0125167

(51) Int. Cl. C09K 11/77; H01L 33/50; C09K 11/64

(52) U.S. Cl. CPC C09K 11/7734; C09K 11/643; H01L 33/502

(57) ABSTRACT

Disclosed are a phosphor, in particular, a green light emitting phosphor, a method for producing the same and a light emitting device package including the same. Provided is a green light emitting phosphor emitting light having a main absorption band in a blue wavelength range and a main peak in a green wavelength range, the green light emitting phosphor represented by the following Formula 1.

SrAl₂(O₁₋₃ₓN₂ₓ)₄ [Formula 1]

### TECHNICAL FIELD

The present invention relates to a phosphor, and more particularly, to a green light emitting phosphor, a method for producing the same and a light emitting device package including the same.

### BACKGROUND ART

Light emitting diodes (LEDs) emitting white light are next-generation light emitting device candidates which can replace fluorescent lights as the most representative conventional lights.

Light emitting diodes have low power consumption as compared to conventional light sources and are environmentally friendly because they do not contain mercury, unlike fluorescent lights. In addition, light emitting diodes have advantages of long lifespan and high response speed as compared to conventional light sources.

There are three methods for producing white light emitting diodes. These methods include implementation of white light by combination of red, green and blue LEDs, implementation of white light by applying a yellow phosphor to blue LEDs and implementation of white light by combination of red, green and blue LEDs with a UV LED.

Of these, implementation of white light by applying the yellow phosphor to blue LEDs is the most representative method for obtaining white light using light emitting diodes.

The green phosphor excited by near-ultraviolet and blue LEDs has a problem of low photo-conversion efficiency at a central wavelength (400 to 450 nm) of an excitation source.

In addition, for this reason, disadvantageously, efficiency of light emitting devices is deteriorated and color representation of display devices and color rendering of lightings are deteriorated due to low color purity of phosphors.

### DISCLOSURE

### Technical Problem

An object of the present invention devised to solve the problem lies on a green light emitting phosphor which has high photo-conversion efficiency and superior color purity using a near-ultraviolet or blue excitation source, a method for producing the same and a light emitting device package using the same.

### Technical Solution

The object of the present invention can be achieved by providing a green light emitting phosphor emitting light having a main absorption band in a blue wavelength range and a main peak in a green wavelength range, the green light emitting phosphor being represented by the following Formula 1.

SrAl₂(O₁₋₃ₓN₂ₓ)₄ [Formula 1]

Light of the green wavelength range may have a central wavelength of 500 nm to 540 nm.

The green wavelength range may include at least a part of a range of 440 nm to 620 nm.

The blue wavelength range may include at least a part of a range of 420 nm to 460 nm.

In Formula 1, x may satisfy 0<x<0.2.

In a further aspect of the present invention, provided herein is a method for producing a green light emitting phosphor, wherein the green light emitting phosphor is produced such that the green light emitting phosphor emits light having a main absorption band in a blue wavelength range and a main peak in a green wavelength range and contains a compound represented by the following Formula 1 in which nitrogen (N) is substituted with oxygen (O).

SrAl₂(O₁₋₃ₓN₂ₓ)₄ [Formula 1]

The production of the green light emitting phosphor may be carried out by synthesis using an oxide raw material and then incorporation of nitrogen.

The production of the green light emitting phosphor may be carried out by synthesis using oxide and nitride raw materials.

The nitride raw material may include at least one of Sr₃N₂ and AlN.

The oxide raw material may include at least one of SrCO₃, Al₂O₃ and Eu₂O₃.

In a further aspect of the present invention, provided herein is a method for producing a green light emitting phosphor, wherein the green light emitting phosphor is produced such that the green light emitting phosphor emits light having a main absorption band in a blue wavelength range and a main peak in a green wavelength range and contains a compound represented by the following Formula 1, produced using at least one of strontium oxide, lutetium oxide and europium oxide raw materials and a nitride raw material.

SrAl₂(O₁₋₃ₓN₂ₓ)₄ [Formula 1]

In a further aspect of the present invention, provided herein is a light emitting device package including the phosphor represented by Formula 1 described above or the phosphor represented by Formula 1 produced by the method described above.

### Advantageous Effects

The present invention has the following advantages.

The present invention can improve efficiency and color representation of light sources of lightings or backlight units (BLUs) for LCD TVs using green phosphors having high photo-conversion efficiency and excellent color purity using near-ultraviolet and blue excitation sources.

A light source having high color purity can be implemented using a green light emitting phosphor and color rendering of lightings can be improved by designing continuous spectrums through combination with a phosphor of an adjacent wavelength when used as lightings.

The technical effects of the present invention are not limited to those described above and other effects not described herein will be clearly understood by those skilled in the art from the following description.

### DESCRIPTION OF DRAWINGS

The accompanying drawings, which are included to provide a further understanding of the invention, illustrate embodiments of the invention and together with the description serve to explain the principle of the invention.

In the drawings:

FIG. 1 illustrates an excitation spectrum of a green light emitting phosphor according to the present invention.

FIG. 2 illustrates an emission spectrum of the green light emitting phosphor according to the present invention.

FIG. 3 illustrates an XRD spectrum of the green light emitting phosphor according to the present invention.

FIG. 4 is a view comparing a peak list of the XRD spectrum of the green light emitting phosphor with an ICOD database of a SrAl₂O₄ crystal structure.

FIG. 5 illustrates an XPS spectrum of the green light emitting phosphor according to the present invention.

FIG. 6 is a schematic view illustrating an example of a light emitting device package using the green light emitting phosphor according to the present invention.

FIG. 7 is a schematic view illustrating another example of a light emitting device package using the green light emitting phosphor according to the present invention.

### BEST MODE

Reference will now be made in detail to the preferred embodiments of the present invention, examples of which are illustrated in the accompanying drawings.

However, the present invention allows various modifications and variations and specific embodiments thereof are exemplified with reference to the drawings and will be described in detail. The present invention should not be construed as limited to the embodiments set forth herein and includes modifications, equivalents and substitutions compliant with the spirit or scope of the present invention defined by the appended claims.

It will be understood that when an element such as a layer, area or substrate is referred to as being “on” another element, it may be directly on the element, or one or more intervening elements may also be present therebetween.

In addition, it will be understood that although terms such as “first” and “second” may be used herein to describe elements, components, areas, layers and/or regions, the elements, components, areas, layers and/or regions should not be limited by these terms.

The present invention provides a green light emitting phosphor which emits light having a main absorption band in a blue wavelength range and a main peak in a green wavelength range and is represented by the following Formula 1.

SrAl₂(O₁₋₃ₓN₂ₓ)₄ [Formula 1]

In this case, light of the green wavelength range may have a central wavelength at 500 nm to 540 nm. That is, the main peak observed in the green wavelength range is present in a wavelength range of 500 nm to 540 nm.

In addition, the green wavelength range may include at least a part of a range of 440 nm to 620 nm.

Here, the blue wavelength range may include at least a part of a range of 420 nm to 460 nm.

Accordingly, such a green light emitting phosphor may be excited by blue light emitted from blue light emitting devices including light emitting diodes (LEDs) and laser diodes (LDs) and then emit green light.

In addition, such a green light emitting phosphor may be excited by near-ultraviolet light and then emit green light.

As such, the present invention provides a green phosphor which has high photo-conversion efficiency and superior color purity using a near-ultraviolet light emitting device and a blue light emitting device as excitation sources.

In Formula 1, X satisfies the condition of 0<x<0.2.

Such a green light emitting phosphor can be obtained by substituting oxygen (O) with nitrogen (N) in the SrAl₂O₄ phosphor, as shown in Formula 1.

That is, the green light emitting phosphor represented by Formula 1 has a structure in which an aluminate matrix is substituted by nitrogen, thus being useful for implementation of white and green light.

Such nitrogen substitution means synthesis performed such that nitrogen (N₂) is disposed in the lattice in the aluminate matrix (SrAl₂O₄) by incorporating nitrogen (N₂) in raw materials and synthesis gas upon synthesis of phosphors.

Green light emitting phosphors used as near-ultraviolet and blue excitation sources may be used as photoluminescent phosphors.

Such light-emitting phosphors have inherent excitation spectrums according to bonding type of phosphors and may be divided into vacuum ultraviolet (VUV), near-ultraviolet (NUV) and blue light-emitting phosphors according to excitation wavelength types.

The green light emitting phosphors according to the present invention can be manufactured using a matrix having excellent excitation efficiency in blue light emitting or near-ultraviolet phosphors among phosphors.

In order to produce phosphors having superior photo-conversion efficiency of near-ultraviolet or blue light (wavelength range of 400 nm to 470 nm), as described above, covalent bonding property is improved and excitation wavelength is shifted to a long wavelength by substituting an oxide phosphor having ionic bonding property by nitrogen.

That is, covalent bonding property can be improved by bonding aluminum (Al) as a Group III element to nitrogen (N) added as a Group V element.

The aluminate matrix described above, the oxide SrAl₂O₄ phosphor, has long afterglow (luminous) characteristics via incorporation of co-activators, thus being useful as luminous phosphor candidate materials.

However, blue excitation light has low excitation characteristics in a blue excitation light region (wavelength range of 440 nm to 470 nm) and thus low photo-conversion efficiency, thus being unsuitable for use in phosphors for white LEDs produced using blue LEDs.

In order to improve low excitation efficiency in blue light of SrAl₂O₄ phosphors, synthesis is performed using nitride raw materials (Sr₃N₂ and AlN) upon synthesis of phosphors, or the SrAl₂O₄ oxide phosphor is obtained as an oxide-nitride phosphor, SrAl₂(O₁₋₃ₓN₂ₓ)₄ shown in Formula 1 by incorporating nitrogen in phosphor lattices using a synthesis gas atmosphere (nitrogen or nitrogen mix gas).

As described above, the SrAl₂(O₁₋₃ₓN₂ₓ)₄phosphor thus synthesized has improved covalent bonding property as nitrogen is substituted in the lattice.

In addition, excitation wavelength is shifted to a long wavelength due to variation in covalent bonding property and efficiency in light sources using blue light is thus improved.

That is, regarding the SrAl₂(O₁₋₃ₓN₂ₓ)₄phosphor suggested by the present invention, excitation wavelength is shifted to long wavelength as compared to aluminate and absorbance in blue light having a wavelength band of 440 nm to 470 nm is thus increased.

Thus, blue light absorbed by phosphors is converted into green light and the green light thus emits. At this time, brightness is improved so that efficiency of white LEDs (phosphor converted LEDs) using blue excitation sources as light sources and lighting and display devices using laser diode (LD) light sources can be improved.

In addition, near-ultraviolet light having a wavelength of 400 nm may be emitted.

Light sources having high color purity can be implemented using green light emitting phosphors to which the excitation wavelength is shifted and color rendering of lightings can be improved by designing continuous spectrums through combination with a phosphor of an adjacent wavelength when used as lightings.

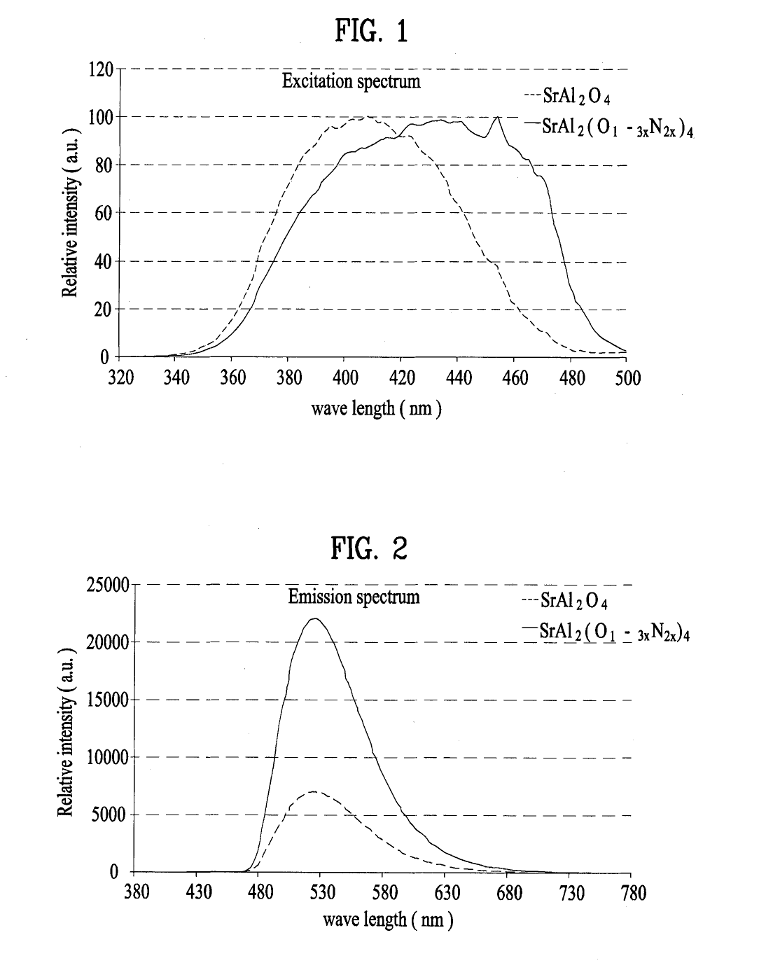

Accordingly, FIG. 1 shows an excitation spectrum of the green light emitting phosphor according to the present invention and FIG. 2 shows an emission spectrum of the green light emitting phosphor according to the present invention.

As can be seen from FIG. 1, the SrAl₂(O₁₋₃ₓN₂ₓ)₄phosphor is shifted to a long wavelength, as compared to the SrAl₂O₄ phosphor represented by a dotted line, has an increased excitation efficiency at a wavelength of 400 nm or more and exhibits a maximum absorbance at a wavelength of 450 nm.

In addition, as can be seen from FIG. 2, the SrAl₂(O₁₋₃ₓN₂ₓ)₄phosphor has greatly improved luminous efficacy in a green wavelength range in an emission spectrum, as compared to the SrAl₂O₄ phosphor represented by a dotted line.

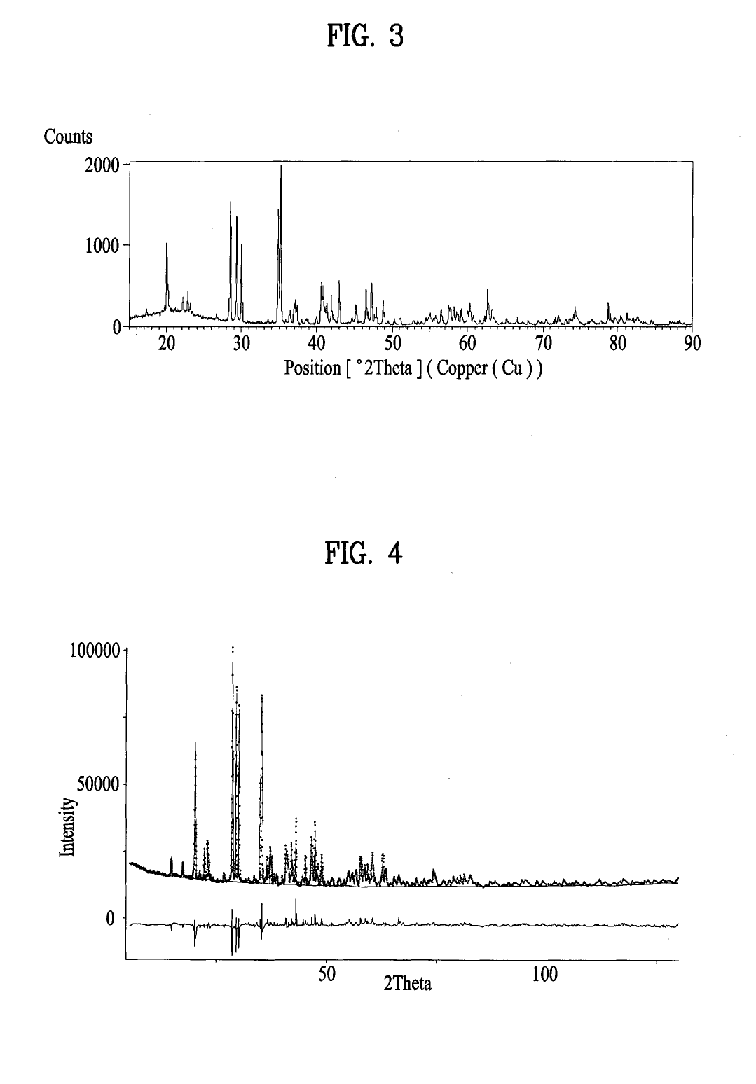

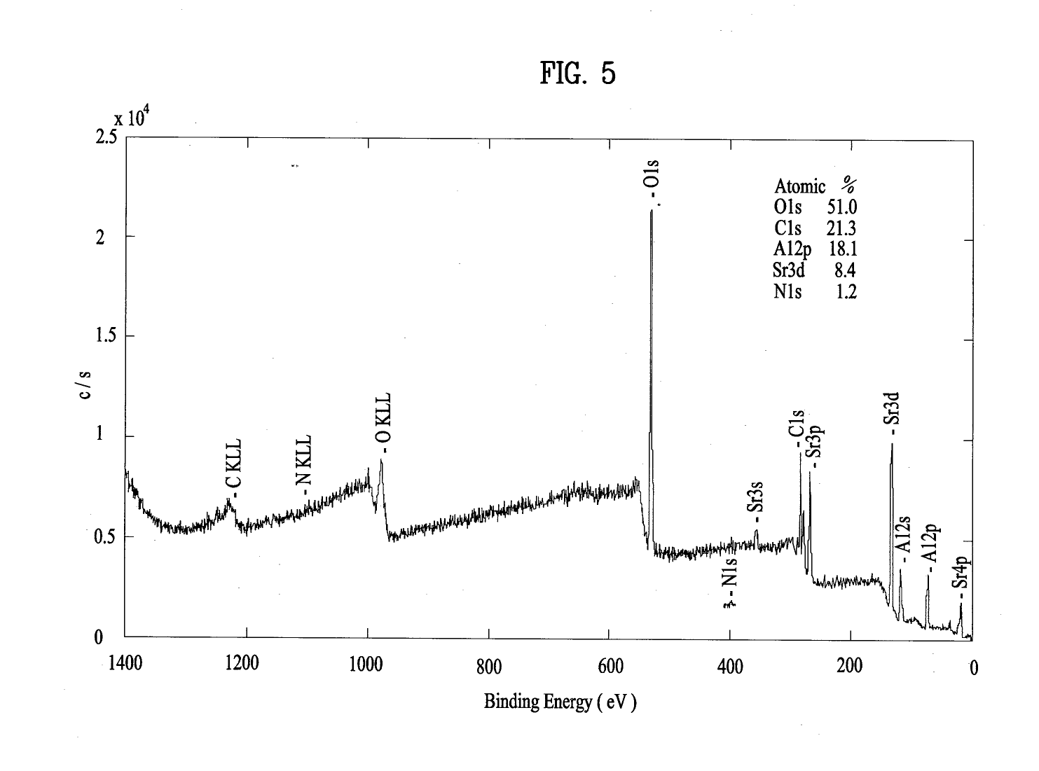

FIG. 3 illustrates an XRD spectrum of the phosphor represented by Formula 1. FIG. 4 is a view for comparing a peak list (top) of the XRD spectrum with the ICOD database (bottom) of a SrAl₂O₄ crystal structure.

That is, as can be seen from FIGS. 3 and 4, the phosphor synthesized according to the present invention has the same crystal structure as SrAl₂O₄.

Meanwhile, FIG. 5 illustrates an XPS spectrum of the phosphor represented by Formula 1.

XPS analysis using the XPS spectrum is a method which analyzes photoelectrons generated upon application of X-rays to sample surfaces.

That is, upon application of X-rays to phosphor samples, electrons confined in the atomic period of the phosphor are released by energy of X-rays. At this time, kinetic energy of these electrons is measured and binding energy of the sample is measured when inherent work functions of the corresponding elements are known.

A ratio of atoms constituting the phosphor based on this value can be obtained and a content of nitrogen in the phosphor represented by Formula 1 is 1.2%, as can be seen from FIG. 5.

Meanwhile, nitrogen and oxygen can be quantitatively and qualitatively analyzed using an ON analyzer.

The ON analyzer may perform analysis using an electrode furnace for melting phosphor samples and may be used for analysis of nitrogen and oxygen gas generated from the melted samples.

The following table 1 shows data obtained by XPS analysis and analysis using an ON analyzer of a SrAl₂O₄ phosphor before nitridation and a SrAl₂(O₁₋₃ₓN₂ₓ)₄ phosphor after nitridation.

TABLE 1

| | | | | | | ON analysis (mol %) | | |
|---|---|---|---|---|---|---|---|---|
| | XPS (atomic %) | | | | | N | O | N/O |
| | Sr | Al | O | N | C | content | content | ratio |
| Before SrAl₂O₄ | 15% | 18.8% | 62.2% | — | 4% | — | 27% | 0% |
| nitridation | | | | | | | | |
| After SrAl₂O₄ | 6.4% | 18.1% | 51% | 1.2% | 21.3% | 0.24% | 27.31% | 0.88% |
| nitridation | | | | | | | | |

As can be seen from Table 1, ratios (atomic ratios; atomic %) of respective components constituting the phosphor obtained by XPS analysis are represented at the left side, and contents and ratios (molar ratios: mol %) of nitrogen and oxygen are represented at the right side obtained using the ON analyzer.

As such, as can be seen from Table 1, SrAl₂(O₁₋₃ₓN₂ₓ)₄ phosphor is produced by nitridation and the ratio of nitrogen is 1.2% (0.24 mol %).

The following Table 2 illustrates central wavelength and relative brightness according to amount of substituted nitrogen (N).

TABLE 2

| Amount of substituted N | Central wavelength | Relative brightness |
|---|---|---|
| 0% | 521 nm | 41% |
| 0.3% | 521 nm | 45% |
| 0.7% | 523 nm | 60% |
| 1.2% | 523 nm | 82% |
| 1.6% | 525 nm | 100% |

As can be seen from Table 2 above, the central wavelength is relatively shifted to a long wavelength and relative brightness is gradually increased, as the amount of substituted nitrogen is increased from 0 to 1.6%.

In consideration of SrAl₂(O₁₋₃ₓN₂ₓ)₄ of Formula 1, X is 0.0082 when the amount of substituted nitrogen is 1.6%.

As described above, the green light emitting phosphor represented by Formula 1 is synthesized as a compound represented by Formula 1 in which nitrogen (N) is substituted with oxygen (O), using strontium, aluminum and europium materials.

The method for substituting nitrogen with oxygen is as follows. First, synthesis is performed using oxide-based strontium, aluminum and europium materials and nitrogen is then incorporated.

In addition, synthesis may be performed using oxide and nitride-based strontium, aluminum and europium materials.

At this time, the nitride raw material may include at least one of strontium nitride and aluminum nitride.

In addition, the oxide material may include at least one of strontium oxide, aluminum oxide and europium oxide.

Hereinafter, examples will be described in detail.

### EXAMPLE

### Example 1

In order to synthesize the green light emitting phosphor represented by Formula 1, synthesis is performed using an oxide raw material at atmospheric pressure (1 atm) and nitridation is then performed.

The oxide raw material may be SrCO₃, Al₂O₃ or Eu₂O₃.

The phosphor described above may be obtained by synthesis at a temperature of 1,450° C. for three hours.

Brightness is increased when a synthesis temperature is increased from 1,200° C., but melting occurs at a synthesis temperature of 1,450° C. or higher and brightness is thus decreased.

### Example 2

In order to synthesize the green light emitting phosphor represented by Formula 1, synthesis is performed using oxide and nitride based raw materials at atmospheric pressure (1 atm).

The oxide raw material may be SrCO₃, Al₂O₃ or Eu₂O₃ and the nitride raw material may be Sr₃N₂ or AlN.

The phosphor may be synthesized by mixing the oxide raw material with the nitride raw material in a stoichiometric ratio at a high pressure (9 atm) while changing the temperature from 1,550° C. to 1,850° C. over 3 hours.

At this time, brightness is the best at 1,750° C., and melting occurs and brightness is thus deteriorated at 1,800° C. or more.

As described above, the present invention can improve efficiency and color representation of light sources of lightings or backlight units (BLUs) for LCD TVs using green phosphors having high photo-conversion efficiency and excellent color purity using near-ultraviolet and blue excitation sources.

A light source having high color purity can be implemented using a green light emitting phosphor and color rendering of lightings can be improved by designing continuous spectrums through combination with a phosphor of an adjacent wavelength when used as lightings.

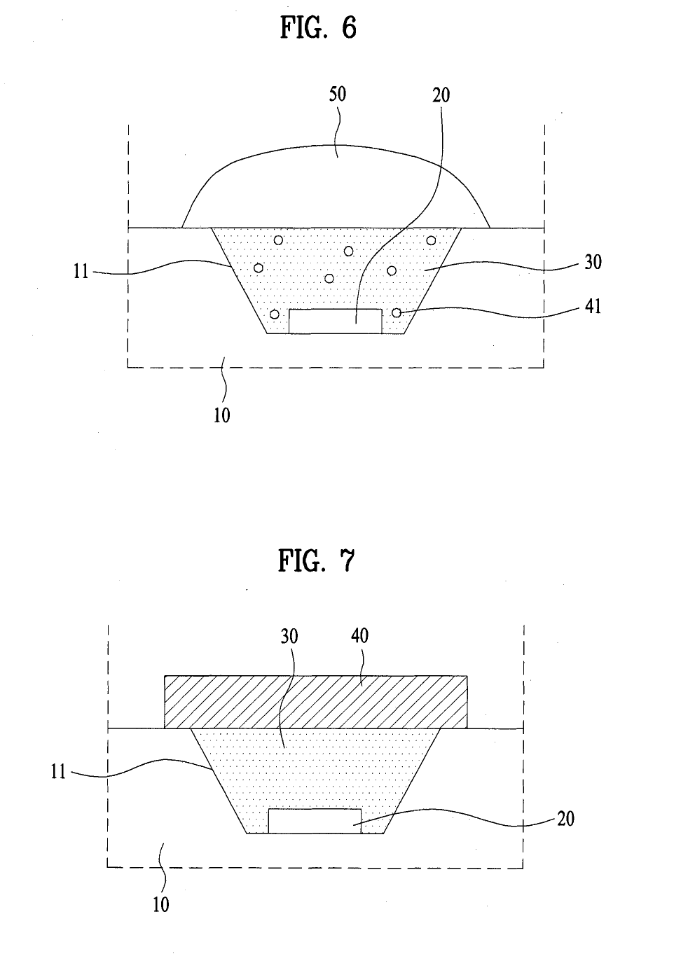

FIG. 6 illustrates an example of a light emitting device package using the green light emitting phosphor according to the present invention.

A light emitting device 20 is mounted inside a reflection cup 11 formed in a package body 10 and the green light emitting phosphor 41 described above is provided in a lower part of the light emitting device 20.

In this case, an encapsulation 30 is disposed on the light emitting device 20 in the reflection cup 11 and the phosphor 41 is homogeneously mixed with the encapsulation 30.

In addition, a lens 50 capable of focusing light emitted from the light emitting device 20 may be provided on the encapsulation 30 and the phosphor 41.

FIG. 7 illustrates another example of a light emitting device package using the green light emitting phosphor according to the present invention.

As shown in the drawing, a phosphor layer 40 is separately produced using the green light emitting phosphor to constitute the light emitting device package.

That is, the light emitting device 20 is mounted inside the reflection cup 11 formed in the package body 10 and the encapsulation 30 is disposed in the upper part of the light emitting device 20.

In this case, the phosphor layer 40 separated from the light emitting device 20 is disposed on the encapsulation 30.

Examples in which the green light emitting phosphor is used for the light emitting device package have been described, but the green light emitting phosphor may be used for other display devices such as PDPs, CRTs and FEDs.

Meanwhile, it will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

### INDUSTRIAL APPLICABILITY

According to the present invention, efficiency and color representation of light sources of lightings or backlight units (BLUs) for LCD TVs can be improved using green phosphors having high photo-conversion efficiency and excellent color purity using near-ultraviolet and blue excitation sources.

1. A green light emitting phosphor emitting light having a main absorption band in a blue wavelength range and a main peak in a green wavelength range, the green light emitting phosphor being represented by the following Formula 1.
SrAl₂(O₁₋₃ₓN₂ₓ)₄ [Formula 1]

2. The green light emitting phosphor according to claim 1 , wherein light of the green wavelength range has a central wavelength of 500 nm to 540 nm.

3. The green light emitting phosphor according to claim 1, wherein the green wavelength range comprises at least a part of a range of 440 nm to 620 nm.

4. The green light emitting phosphor according to claim 2, wherein the blue wavelength range comprises at least a part of a range of 420 nm to 460 nm.

5. The green light emitting phosphor according to claim 1 , wherein x satisfies 0<x<0.2.

6. The green light emitting phosphor according to claim 5, wherein the green light emitting phosphor exhibits maximum absorbance at 440 nm to 460 nm.

7. A method for producing a green light emitting phosphor, wherein the green light emitting phosphor is produced such that the green light emitting phosphor emits light having a main absorption band in a blue wavelength range and a main peak in a green wavelength range and comprises a compound represented by the following Formula 1 in which nitrogen (N) is substituted with oxygen (O).
SrAl₂(O₁₋₃ₓN₂ₓ)₄ [Formula 1]

8. The method according to claim 7, wherein the production of the green light emitting phosphor is carried out by synthesis using an oxide raw material and then incorporation of nitrogen.

9. The method according to claim 7, wherein the production of the green light emitting phosphor is carried out by synthesis using oxide and nitride raw materials.

10. The method according to claim 9, wherein the nitride raw material comprises at least one of Sr₃N₂ and AlN.

11. The method according to claim 8 or 9, wherein the oxide raw material comprises at least one of SrCO₃, Al₂O₃ and Eu₂O₃.

12. The method according to claim 7, wherein the green wavelength range comprises at least a part of a range of 420 nm to 460 nm.

13. The method according to claim 7, wherein the blue wavelength range comprises at least a part of a range of 440 nm to 620 nm.

14. The method according to claim 7, wherein x is 0<x<0.2.

15. A method for producing a green light emitting phosphor,
wherein the green light emitting phosphor is produced such that the green light emitting phosphor emits light having a main absorption band in a blue wavelength range and a main peak in a green wavelength range and comprises a compound represented by the following Formula 1, produced using at least one of strontium oxide, lutetium oxide and europium oxide raw materials and a nitride raw material.
SrAl₂(O₁₋₃ₓN₂ₓ)₄ [Formula 1]

16. The method according to claim 15, wherein light of the green wavelength range has a central wavelength of 500 nm to 540 nm.

17. The method according to claim 15, wherein the green wavelength range comprises at least a part of a range of 420 nm to 460 nm.

18. The method according to claim 15, wherein the green wavelength range comprises at least a part of a range of 440 nm to 620 nm.

19. The method according to claim 15, wherein x satisfies 0<x<0.2.

20. A light emitting device package comprising the phosphor represented by Formula 1 according to claim 1.
